(19) United States
(12) Patent Application Publication
(10) Pub. No.: US 2020/0231731 A1
(43) Pub. Date: Jul. 23, 2020

(54) PROCESS THAT ENABLES THE CREATION OF NANOMETRIC STRUCTURES BY SELF-ASSEMBLY OF DIBLOCK COPOLYMERS

(71) Applicants: Arkema France, Colombes (FR); Institut Polytechnique De Bordeaux, Talence Cedex (FR); Centre National De La Recherche Scientifique, Paris Cedex 14 (FR); Universite De Bordeaux, Bordeaux (FR)

(72) Inventors: Christophe NAVARRO, Bayonne (FR); Celia Nicolet, Sauvagnon (FR); Karim Aissou, Begles (FR); Muhammad Mumtaz, Bordeaux (FR); Eric Cloutet, Begles (FR); Cyril Brochon, Merignac (FR); Guillaume Fleury, Bordeaux (FR); Georges Hadziioannou, Leognan (FR)

(73) Assignee: Arkema France, Colombes (FR)

(21) Appl. No.: 15/768,976

(22) PCT Filed: Oct. 7, 2016
(86) PCT No.: PCT/FR2016/052592

§ 371 Date: Apr. 17, 2018

(30) Foreign Application Priority Data
Oct. 23, 2015 (FR) 1560161

(51) Int. Cl. C08F 297/02; C08G 77/442; C09D 153/00; C08G 77/60; H01L 21/027

(52) U.S. Cl. CPC C08F 297/02; C08G 77/442; B82Y 30/00; C08G 77/60; H01L 21/0271; C09D 153/00

(57) ABSTRACT

A process for preparing a nanostructured assembly by annealing a composition comprising a block copolymer on a surface. The block copolymer includes a first block resulting from the polymerization of at least one cyclic monomer having a structure as described herein. The block copolymer also includes a second block that includes a vinyl aromatic monomer.

The invention relates to a process that enables the creation of nanometric structures by self-assembly of diblock copolymers, one of the blocks of which is obtained by (co)polymerization of at least one cyclic entity corresponding to formula (I) and the other block of which is obtained by (co)polymerization of at least one vinyl aromatic monomer

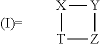

where X=Si(R₁,R₂); Ge(R₁,R₂)

Z=Si(R₃,R₄); Ge(R₃,R₄); O; S; C(R₃,R₄)

Y=O; S; C(R₅,R₆)

T=O; S; C(R₇,R₈)

R₁, R₂, R₃, R₄, R₅, R₆, R₇, R₈ are selected from hydrogen, linear, branched or cyclic alkyl groups, with or without heteroatoms, and aromatic groups with or without heteroatoms.

The invention also relates to the use of these materials in the fields of lithography in which block copolymer films constitute lithography masks of which one or other of the constituent domains of each block can be selectively degraded, and of information storage in which block copolymer films make it possible to localize magnetic particles in one or other of the constituent domains of each block that can be selectively degraded. The process also applies to the production of porous membranes or of catalyst supports of which one or other of the constituent domains of each block can be selectively degraded in order to obtain a porous structure. The process advantageously applies to the field of nanolithography using block copolymer masks of which one or other of the constituent domains of each block can be selectively degraded in order to obtain positive or negative resins. The invention also relates to the block copolymer masks obtained according to the process of the invention and the positive or negative resins thus obtained, the block copolymer films containing magnetic particles in one or other of the constituent domains of each block that can be selectively degraded, and the porous membranes or catalyst supports of which one or other of the constituent domains of each block are selectively degraded in order to obtain a porous structure.

The development of nanotechnologies has made it possible to constantly miniaturize products in the field of microelectronics and micro-electro-mechanical systems (MEMS) in particular. Today, conventional lithography techniques no longer make it possible to meet these constant needs for miniaturization, as they do not make it possible to produce structures with dimensions of less than 60 nm. It has therefore been necessary to adapt the lithography techniques and to create etching masks which make it possible to create increasingly small patterns with a high resolution. With block copolymers, it is possible to structure the arrangement of the constituent blocks of the copolymers by phase segregation between the blocks, thus forming nanodomains, at scales of less than 50 nm. Due to this ability to be nanostructured, the use of block copolymers in the fields of electronics or optoelectronics is now well known.

Among the masks studied for carrying out nanolithography, block copolymer films, in particular based on polystyrene-poly(methyl methacrylate), denoted hereinbelow as PS-b-PMMA, appear to be very promising solutions since they make it possible to create patterns with a high resolution. In order to be able to use such a block copolymer film as an etching mask, one block of the copolymer must be selectively removed in order to create a porous film of the residual block, the patterns of which may be subsequently transferred by etching to an underlying layer. Regarding the PS-b-PMMA film, the PMMA (poly(methyl methacrylate)) block is removed selectively in order to create a mask of residual PS (polystyrene). For these masks, only the PMMA domains can be selectively degraded; the converse does not result in sufficient selectivity of degradation of the PS domains.

In order to create such masks, the nanodomains must be oriented perpendicular to the surface of the underlying layer. Such structuring of the domains requires particular conditions such as the preparation of the surface of the underlying layer, but also the composition of the block copolymer.

The ratios between the blocks make it possible to control the shape of the nanodomains and the molecular weight of each block makes it possible to control the size of the blocks. Another very important factor is the phase segregation factor, also referred to as the Flory-Huggins interaction parameter and denoted by “χ”. Specifically, this parameter makes it possible to control the size of the nanodomains. More particularly, it defines the tendency of the blocks of the block copolymer to separate into nanodomains. Thus, the product χN of the degree of polymerization N, and of the Flory-Huggins parameter χ, gives an indication as to the compatibility of two blocks and whether they may separate. For example, a diblock copolymer of symmetrical composition separates into microdomains if the product χN is greater than 10.5. If this product χN is less than 10.5, the blocks mix together and phase separation is not observed.

Due to the constant needs for miniaturization, it is sought to increase this degree of phase separation, in order to produce nanolithography masks that make it possible to obtain very high resolutions, typically of less than 20 nm, and preferably of less than 10 nm.

In Macromolecules, 2008, 41, 9948, Y. Zhao et al. estimated the Flory-Huggins parameter for a PS-b-PMMA block copolymer. The Flory-Huggins parameter χ obeys the following equation: χ=a+b/T, where the values a and b are constant specific values dependent on the nature of the blocks of the copolymer and T is the temperature of the heat treatment applied to the block copolymer in order to enable it to organize itself, that is to say in order to obtain a phase separation of the domains, an orientation of the domains and a reduction in the number of defects. More particularly, the values a and b respectively represent the entropic and enthalpic contributions. Thus, for a PS-b-PMMA block copolymer, the phase segregation factor obeys the following equation: χ=0.0282+4.46/T. Consequently, even though this block copolymer makes it possible to generate domain sizes of slightly less than 20 nm, it does not make it possible to go down much lower in terms of domain size, due to the low value of its Flory-Huggins interaction parameter χ. This low value of the Flory-Huggins interaction parameter therefore limits the advantage of block copolymers based on PS and PMMA for the production of structures having very high resolutions.

In order to circumvent this problem, M. D. Rodwogin et al., ACS Nano, 2010, 4, 725, demonstrated that it is possible to change the chemical nature of the two blocks of the block copolymer in order to very greatly increase the Flory-Huggins parameter χ and to obtain a desired morphology with a very high resolution, that is to say the size of the nanodomains of which is less than 20 nm. These results have in particular been demonstrated for a PLA-b-PDMS-b-PLA (polylactic acid-polydimethylsiloxane-polylactic acid) triblock copolymer.

H. Takahashi et al., Macromolecules, 2012, 45, 6253, studied the influence of the Flory-Huggins interaction parameter χ on the kinetics of copolymer assembly and of reduction of defects in the copolymer. They in particular demonstrated that, when this parameter χ becomes too great, there is generally a considerable slowing of the assembly kinetics, and of the phase segregation kinetics, also leading to a slowing of the kinetics of defect reduction at the time of domain organization. Another problem, reported by S. Ji et al., ACS Nano, 2012, 6, 5440, is also faced when considering the organization kinetics of block copolymers containing a plurality of blocks that are all chemically different from one another. Specifically, the kinetics of diffusion of the polymer chains, and consequently the kinetics of organization and defect reduction within the self-assembled structure, are dependent on the segregation parameters χ between each of the various blocks. Moreover, these kinetics are also slowed down due to the multiblock architecture of the copolymer, since the polymer chains then have fewer degrees of freedom for becoming organized with respect to a block copolymer comprising fewer blocks.

U.S. Pat. Nos. 8,304,493 and 8,450,418 describe a process for modifying block copolymers, and also modified block copolymers. These modified block copolymers have a modified value of the Flory-Huggins interaction parameter χ, such that the block copolymer has nanodomains of small sizes.

Due to the fact that PS-b-PMMA block copolymers already make it possible to achieve dimensions of the order of 20 nm, the Applicant has sought a solution for modifying this type of block copolymer in order to obtain a good compromise regarding the Flory-Huggins interaction parameter χ, and the self-assembly speed and temperature.

Application WO 2015087003 introduces improvements into the PS-b-PMMA system; however, the films obtained do not allow the production of masks in which the respective constituent domains of the blocks of the block copolymers can be selectively eliminated.

Surprisingly, it has been discovered that diblock copolymers, one of the blocks of which results from the polymerization of monomers comprising at least one cyclic entity corresponding to formula (I) and the other block of which comprises a vinyl aromatic monomer, have the following advantages when they are deposited on a surface:
Rapid self-assembly kinetics (between 1 and 20 minutes) for low molecular weights leading to domain sizes well below 10 nm, at low temperatures (between 333 K and 603 K, and preferably between 373 K and 603 K).
The presence of entities resulting from monomers of the family of (I), silicon or germanium carbide precursors after plasma treatment or treatment by pyrolysis, that make it possible to obtain hard masks during the mask etching step.
The orientation of the domains during the self-assembly of such block copolymers does not require preparation of the support (no neutralization layer), the orientation of the domains being governed by the thickness of the block copolymer film deposited.
Selective elimination of one or other of the constituent domains of these diblock copolymers which makes possible the production of positive or negative resins, that can be used in the fields of lithography, porous membranes or catalyst supports or magnetic particle supports.

### SUMMARY OF THE INVENTION

The invention relates to a nanostructured assembly process using a composition comprising a diblock copolymer, one of the blocks of which results from the polymerization of at least one monomer corresponding to the following formula (I):

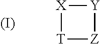

where X=Si(R₁,R₂); Ge(R₁,R₂)

Z=Si(R₃,R₄); Ge(R₃,R₄); O; S; C(R₃,R₄)

Y=O; S; C(R₅,R₆)

T=O; S; C(R₇,R₈)

with R₁═R₂ and R₃═R₄ and R₅═R₆ and R₇═R₈ are selected from hydrogen, linear, branched or cyclic alkyl groups, with or without heteroatoms, and aromatic groups with or without heteroatoms, the other block comprising a vinyl aromatic monomer, and comprising the following steps:
dissolving the block copolymer in a solvent,
depositing this solution on a surface,
annealing.

### DETAILED DESCRIPTION

The term “surface” is understood to mean a surface which can be flat or non-flat.

The term “annealing” is understood to mean a step of heating at a certain temperature that enables the evaporation of the solvent, when it is present, and that allows the establishment of the desired nanostructuring in a given time (self-assembly).

The term “annealing” is also understood to mean the establishment of the nanostructuring of the block copolymer film when said film is subjected to a controlled atmosphere of one or more solvent vapours, these vapours giving the polymer chains sufficient mobility to become organized by themselves on the surface. The term “annealing” is also understood to mean any combination of the abovementioned two methods.

The monomeric entities used for the polymerization in one of the blocks of the diblock copolymers used in the process of the invention are represented by the following formula (I):

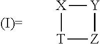

where X=Si(R₁,R₂); Ge(R₁,R₂)

Z=Si(R₃,R₄); Ge(R₃,R₄); O; S; C(R₃,R₄);

Y=O; S; C(R₅,R₆)

T=O; S; C(R₇,R₈)

R₁, R₂, R₃, R₄, R₅, R₆, R₇, R₈ are selected from hydrogen, linear, branched or cyclic alkyl groups, with or without heteroatoms, and aromatic groups with or without heteroatoms and R₁ ═R₂ and R₃═R₄ and R₅═R₆ and R₇═R₈.

Preferably, X=Si(R₁,R₂) where R₁ and R₂ are linear alkyl groups, and preferably methyl groups, Y=C(R₅,R₆) where R₅ and R₆ are hydrogen atoms, Z=C(R₃,R₄) where R₃ and R₄ are hydrogen atoms, T=C(R₇,R₈) where R₇ and R₈ are hydrogen atoms.

The monomeric entities used in the other block of the diblock copolymers used in the process of the invention comprise a vinyl aromatic monomer such as styrene or substituted styrenes, in particular alpha-methylstyrene, silylated styrenes in weight proportions of between 50% and 100%, preferably between 75% and 100% and preferably between 90% and 100% within this other block. According to one preference of the invention, the monomeric entities used in the other block of the diblock copolymers used in the process of the invention consist of styrene.

The block copolymers used in the invention are prepared by sequential anionic polymerization. Such a synthesis is well known to a person skilled in the art. A first block is prepared according to a protocol described by Yamaoka et al., Macromolecules, 1995, 28, 7029-7031.

The next block is constructed in the same way by sequentially adding the monomers involved. One of the advantages of combining the sequence of the polymerization of the block comprising the monomer (I) with vinyl aromatic monomers, and more particularly styrene, is, on the one hand, the non-deactivation of a part of the block comprising the entity (I) during the synthesis of the second block and, on the other hand, the fact that there is no need to add diphenyl ethylene to adjust the reactivity of the species. In the present case, the small difference in PKa of the conjugate acid of the anion which propagates and in the PKa of the conjugate acid of the initiating species (typically less than 2) also allows the incorporation of vinyl aromatic monomers and more particularly styrene (between 0% and 75%, and preferably between 0% and 50%) within the block comprising the entity (I), thereby allowing fine adjustment of the Flory-Huggins parameter.

Thus, a diblock copolymer comprising, in the first block, at least one monomer corresponding to formula (I) and a vinyl aromatic compound, and more particularly styrene, the other block comprising a styrene compound and more particularly styrene, is particularly advantageous in the context of the process of the invention and constitutes another aspect of the invention.

The invention thus also relates to the diblock copolymers, the first block of which results from the polymerization of at least one monomer corresponding to formula (I) and a vinyl aromatic compound, and more particularly styrene, the other block of which results from the polymerization of at least one vinyl aromatic compound and more particularly styrene.

Once the block copolymer has been synthesized, it is dissolved in a suitable solvent then deposited on a surface according to techniques known to a person skilled in the art such as for example the spin coating, doctor blade coating, knife coating system or slot die coating system technique, but any other technique may be used such as dry deposition, that is to say deposition without involving a predissolution.

A heat treatment or treatment by solvent vapour, a combination of the two treatments, or any other treatment known to a person skilled in the art which makes it possible for the block copolymer chains to become correctly organized while becoming nanostructured, and thus to establish the film having an ordered structure, is subsequently carried out.

The films thus obtained have a thickness up to 200 nm.

Mention will be made, among the favoured surfaces, of silicon, silicon having a native or thermal oxide layer, hydrogenated or halogenated silicon, germanium, hydrogenated or halogenated germanium, platinum and platinum oxide, tungsten and oxides, gold, titanium nitrides and graphenes. Preferably, the surface is inorganic and more preferably silicon. More preferably still, the surface is silicon having a native or thermal oxide layer.

The surfaces can be said to be “free” (flat or non-flat and homogeneous surface, both from a topographical and from a chemical viewpoint) or can exhibit structures for guidance of the block copolymer “pattern”, whether this guidance is of the chemical guidance type (known as “guidance by chemical epitaxy”) or physical/topographical guidance type (known as “guidance by graphoepitaxy”).

It will be noted in the context of the present invention, even though it is not excluded, that it is not necessary to carry out a neutralization step (as is the case generally in the prior art) by the use of a suitably chosen random copolymer. This presents a considerable advantage since this neutralization step is disadvantageous (synthesis of the random copolymer of particular composition, deposition on the surface). The orientation of the block copolymer is defined by the thickness of the block copolymer film deposited or coated by using solvent vapour annealing. It is obtained in a relatively short time, of between 1 and 20 minutes limits included and preferably of between 1 and 5 minutes, and at temperatures between 333 K and 603 K and preferably between 373 K and 603 K and more preferably between 373 K and 403 K.

When a neutralization step proves to be necessary, another advantage in the choice of the monomers used in the diblock copolymers used in the process of the invention is the choice of the small difference in PKa of the conjugate acid of the anion which propagates and in the PKa of the conjugate acid of the initiating species. This small difference in PKa (typically less than 2) allows random linking of the monomers and thus makes it possible to easily prepare a random copolymer allowing neutralization of the surface, with as appropriate a functionalization allowing grafting of the random copolymer onto the chosen surface. Thus, the surface can be treated with a random copolymer thus synthesized prior to the deposition of the diblock copolymer, said random copolymer comprising the entity (I) and a vinyl aromatic monomer, preferably styrene. The invention thus also relates to a process in which the surface is treated with a random copolymer comprising entities (I) and a vinyl aromatic monomer, preferably styrene, prior to the deposition of the diblock copolymer, and also a random copolymer comprising entities (I) and a vinyl aromatic monomer, preferably styrene, with preferably X=Si, Y, Z, T=C, and R₁═R₂═CH₃, R₃═R₄═R₅═R₆═R₇═R₈═H.

Because of the possible selective elimination of one or other of the constituent domains of these diblock copolymers used in the process of the invention by a plasma suitable for the domain to be eliminated, the process of the invention makes possible the production of positive or negative resins, that can be used in the fields of lithography, porous membranes or catalyst supports or magnetic particle supports.

### Example 1: Synthesis of poly(1,1-dimethylsilacyclobutane)-block-PS (PDMSB-b-PS)

1,1-Dimethylsilacyclobutane (DMSB) is a monomer of formula (I) where X=Si(CH₃)₂, Y=Z=T=CH₂.

The polymerization is carried out anionically in a 50/50 (vol/vol) THF/heptane mixture at −50° C. by sequential addition of the two monomers with the secondary butyl lithium initiator (sec-BuLi). Typically, lithium chloride (85 mg), 20 ml of THF and 20 ml of heptane are introduced into a flamed, dry 250 ml round-bottomed flask equipped with a magnetic stirrer. The solution is cooled to −40° C. Next, 0.3 ml of sec-BuLi (secondary butyl lithium) at 1 mol/l is introduced, followed by an addition of 1 g of 1,1-dimethylsilacyclobutane. The reaction mixture is stirred for 1 h and then 0.45 ml of styrene is added and the reaction mixture is kept stirring for 1 h. The reaction is completed by an addition of degassed methanol and then the reaction medium is concentrated by partial evaporation of the reaction medium solvent, followed by a precipitation in methanol. The product is then recovered by filtration and dried in an oven at 50° C. overnight.

The macromolecular characteristics of the block copolymer synthesized in Example 1 are reported in the table below.

| | | | Volume fraction |
|---|---|---|---|
| PDMSB-b-PS | Mn (kg/mol) | D | PDMSB |
| Example 1 | 28.2 | 1.13 | 0.2 |

The molecular weights and the dispersities, corresponding to the ratio of weight-average molecular weight (Mw) to number-average molecular weight (Mn), are obtained by SEC (size exclusion chromatography), using two Agilent 3 μm ResiPore columns in series, in a THF medium stabilized with BHT, at a flow rate of 1 ml/min, at 40° C., with samples at a concentration of 1 g/l, with prior calibration with graded samples of polystyrene using an Easical PS-2 prepared pack.

### Example 2: Synthesis of poly(1,1-dimethylsilacyclobutane)-block-PS (PDMSB-b-PS)

The procedure is carried out in the same way as for Example 1: the polymerization is carried out anionically in a 50/50 (vol/vol) THF/heptane mixture at −50° C. by sequential addition of the two monomers with the secondary butyl lithium initiator (sec-BuLi). Typically, lithium chloride (80 mg), 30 ml of THF and 30 ml of heptane are introduced into a flamed, dry 250 ml round-bottomed flask equipped with a magnetic stirrer. The solution is cooled to −40° C. Next, 0.18 ml of sec-BuLi (secondary butyl lithium) at 1 mol/l is introduced, followed by an addition of 1.3 ml of 1,1-dimethylsilacyclobutane. The reaction mixture is stirred for 1 h and then 4.4 ml of styrene are added and the reaction mixture is kept stirring for 1 h. The reaction is completed by an addition of degassed methanol and then the reaction medium is concentrated by partial evaporation of the reaction medium solvent, followed by a precipitation in methanol. The product is then recovered by filtration and dried in an oven at 50° C. overnight.

The macromolecular characteristics of the block copolymer synthesized in Example 2 are reported in the table below.

| | | | Volume fraction |
|---|---|---|---|
| PDMSB-b-PS | Mn (kg/mol) | D | PDMSB |
| Example 2 | 12.2 | 1.13 | 0.28 |

The molecular weights and the dispersities, corresponding to the ratio of weight-average molecular weight (Mw) to number-average molecular weight (Mn), are obtained by SEC (size exclusion chromatography), using two Agilent 3 μm ResiPore columns in series, in a THF medium stabilized with BHT, at a flow rate of 1 ml/min, at 40° C., with samples at a concentration of 1 g/I, with prior calibration with graded samples of polystyrene using an Easical PS-2 prepared pack.

### Example 3: Production of the Films

The films of Example 1 were prepared on silicon substrates by spin coating using a 1% by weight solution in THF. The promotion of the self-assembly inherent in the phase segregation between the blocks of the copolymer was obtained by exposure of the film for 3 h under a continuous stream of THF vapour produced by nitrogen bubbling in a solution of THF. This device makes it possible to control the vapour pressure of the THF in the exposure chamber by dilution of the latter using a separate stream of pure nitrogen such that the total mixture consists of 8 sccm of THF vapour for 2 sccm of pure nitrogen. Such a mixture has the effect of saturating the film with solvent without causing its de-wetting with respect to the surface of the substrate.

The films thus exposed are then fixed in air by rapidly removing the lid of the exposure chamber.

A plasma treatment (CF₄/O₂ RIE plasma, 40 W, 17 sccm CF₄ and 3 sccm O₂ for 30 seconds) makes it possible to eliminate the PDMSB domains in order to generate a positive resin before examination by AFM microscopy. Likewise, a plasma treatment (UV/O₃ 5 minutes then oxygen-rich plasma, 90 W, 10 sccm of oxygen, 5 sccm of argon for 30 seconds) makes it possible to eliminate the PS domains in order to generate a negative resin before examination by AFM microscopy.

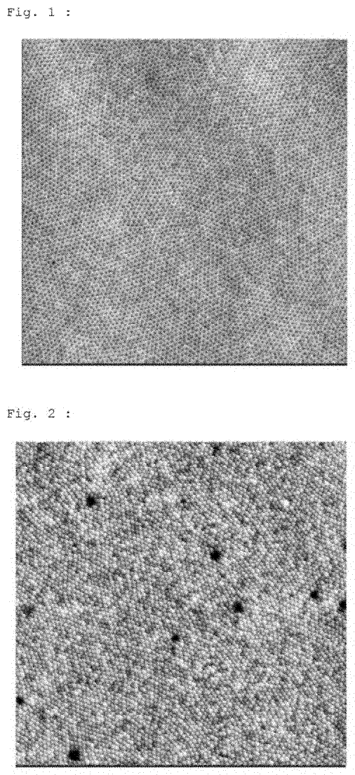

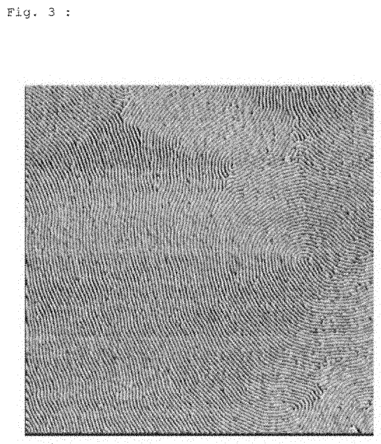

The AFM images are given in FIGS. 1 to 3 and correspond to the copolymers from Examples 1 (FIGS. 1 and 2) and 2 (FIG. 3).

FIG. 1 is a topographic AFM image (3×3 μm) showing the result of the self-assembly in a thin film of the block copolymer of Example 1 exhibiting cylinders oriented perpendicular to the substrate, after elimination of the PDMSB phase (positive resin).

FIG. 2 is a topographic AFM image (3×3 μm) showing the result of the self-assembly in a thin film of the same block copolymer exhibiting cylinders oriented perpendicular to the substrate, after elimination of the PS phase (negative resin).

### Example 4

The film of Example 2 is heat-treated at 200° C. for 20 min.

FIG. 3 (2×2 μm) shows an assembly of the copolymer of Example 2 with a thickness of 70 nm, and a period of 18.5 nm, after fluorinated RIE plasma treatment.

1-15: (canceled)

16. A process of preparing a nanostructured assembly, comprising:
(a) annealing a composition comprising a block copolymer on a surface,
wherein the block copolymer comprises a first block resulting from the polymerization of at least one monomer represented by formula (I): 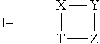
wherein
Si(R₁,R₂) or Ge(R₁,R₂),
Z=Si(R₃,R₄), Ge(R₃,R₄), O, S, or C(R₃,R₄),
Y=O, S, or C(R₅,R₆), and
T=O, S, or C(R₇,R₈),
wherein
R₁═R₂ and R₃═R₄ and R₅═R₆ and R₇═R₈ are selected from hydrogen, linear, branched or cyclic alkyl groups, with or without heteroatoms, and aromatic groups with or without heteroatoms, and
wherein the block copolymer comprises a second block comprising a vinyl aromatic monomer.

17. The process of claim 16, wherein the composition further comprises a solvent.

18. The process of claim 17, further comprising prior to (a):
(b) dissolving the block copolymer in the solvent to produce the composition.

19. The process of claim 18, further comprising, prior to (a) and subsequent to (b):
(c) depositing the composition on the surface.

20. The process of claim 16, wherein X=Si(R₁,R₂), Z=C(R₃,R₄) Y=C(R₅,R₆) and T=C(R₇,R₈).

21. The process of claim 20, wherein R₁═R₂═CH₃ and R₃═R₄═R₅═R₆═R₇═R₈═H.

22. The process of claim 16, wherein the second block comprises a vinyl aromatic monomer.

23. The process of claim 22, wherein the vinyl aromatic monomer is styrene.

24. The process of claim 16, herein the first block comprises a vinyl aromatic monomer.

25. The process of claim 24, wherein the vinyl aromatic monomer is styrene.

26. The process of claim 16, wherein the block copolymer is a diblock copolymer.

27. The process of claim 16, further comprising treating the surface with a random copolymer comprising the monomer represented by formula (I) and a vinyl aromatic monomer.

28. The process claim 27, wherein the vinyl aromatic monomer is styrene.

29. The process of claim 16, wherein the orientation of the block copolymer is defined by the thickness of a block copolymer film deposited or coated by using solvent vapor annealing.

30. The process of claim 16, wherein the surface is free.

31. The process of claim 16, wherein the surface is guided.

32. The process of claim 16, which is applied to the field of lithography, the production of porous membranes, the production of catalyst supports, or the production of magnetic particle supports.

33. A mask of positive or negative resin of a film obtained according to the process of claim 16 and treated by a plasma that specifically degrades the specific domains of one of the two blocks of the block copolymer.

34. A random copolymer comprising the monomer represented by formula (I) and styrene, 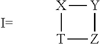
wherein
X=Si(R₁,R₂) or Ge(R₁,R₂),
Z=Si(R₃,R₄), Ge(R₃,R₄), O, S, or C(R₃,R₄),
Y=O, S, or C(R₅,R₆), and
T=O, S or C(R₇R₈), and
wherein
R₁═R₂ and R₃═R₄ and R₅═R₆ and R₇═R₈ are selected from hydrogen, linear, branched or cyclic alkyl groups, with or without heteroatoms, and aromatic groups with or without heteroatoms.

35. The random copolymer of claim 34, wherein
X=Si,
Y, Z, T=C, and
R₁═R₂═CH₃, R₃═R₄═R₅═R₆═R₇═R₈═H.
